(19) United States
(12) Patent Application Publication
(10) Pub. No.: US 2026/0182429 A1
(43) Pub. Date: Jun. 25, 2026

(54) CHIP PACKAGE WITH AN INTERPOSER HAVING A GLASS CORE AND A SUBSTRATE HAVING A GLASS CORE

(71) Applicant: Advanced Micro Devices, Inc., Santa Clara, CA (US)

(72) Inventors: Rajesh Kumar NEERUKATTI, Austin, TX (US); Kaushik MYSORE, Austin, TX (US); Deepak Vasant KULKARNI, Austin, TX (US)

(21) Appl. No.: 18/990,655

(22) Filed: Dec. 20, 2024

(51) Int. Cl. H01L 23/15; G02B 6/42; H01L 23/00; H01L 23/13; H01L 23/498; H01L 23/538; H01L 25/065

(52) U.S. Cl. CPC H10W 70/692; G02B 6/421; H10W 70/611; H10W 70/614; H10W 70/68; H10W 70/685; H10W 90/00; H10W 72/072; H10W 90/724

(57) ABSTRACT

A chip package for a computer system includes a substrate including a glass substrate core, first redistribution layers disposed on a first surface of the glass substrate core, and second redistribution layers disposed on a second surface of the glass substrate core. The chip package further includes an interposer including a glass interposer core, third redistribution layers disposed on a first surface of the glass interposer core, and fourth redistribution layers disposed on a second surface of the glass interposer core. Further, the chip package includes a first chip die mounted to a first surface of the interposer.

### TECHNICAL FIELD

Examples of the present disclosure generally relate to a chip package, and in particular, to a chip package including an interposer and substrate having glass cores.

### BACKGROUND

Electronic devices, such as tablets, computers, copiers, digital cameras, smart phones, control systems and automated teller machines, among others, often employ electronic components, which leverage chip packages for increased functionality and higher component density. Conventional chip packaging schemes often utilize a package substrate, often in conjunction with a through-silicon-via (TSV) interposer, to enable a plurality of integrated circuit (IC) dies to be mounted to a single package substrate. The IC dies may include memory, logic or other IC devices.

Wafer-level multi-chip packaging technology has been develop to incorporate multiple dies side-by-side on a silicon interposer in order to achieve a better interconnect density and performance. The individual chips are bonded through micro-bumps on a silicon interposer forming a chip-on-wafer (CoW). The CoW is then subsequently thinned such that through silicon via perforations are exposed. This is followed by C4 bump formation and singulation. The CoWoS package is completed through bonding to a package substrate. However, wafer based packaging for large chip modules has limited scalability due to the reticle limit.

Therefore, a need exists for an improved chip package that is scalable for larger chip modules.

### SUMMARY

In one example, a chip package includes a substrate including a glass substrate core, first redistribution layers disposed on a first surface of the glass substrate core, and second redistribution layers disposed on a second surface of the glass substrate core. The chip package further includes an interposer including a glass interposer core, third redistribution layers disposed on a first surface of the glass interposer core, and fourth redistribution layers disposed on a second surface of the glass interposer core. Further, the chip package includes a first chip die mounted to a first surface of the interposer.

In one example, a computer system including an integrated circuit device and a chip package. The chip package is connected to the integrated circuit device. The chip package includes a substrate, an interposer, and a first chip die. The substrate including a glass substrate core, first redistribution layers disposed on a first surface of the glass substrate core, and second redistribution layers disposed on a second surface of the glass substrate core. The interposer includes a glass interposer core, third redistribution layers disposed on a first surface of the glass interposer core, and fourth redistribution layers disposed on a second surface of the glass interposer core. The first chip die is mounted to a first surface of the interposer.

In one example, a method for fabricating a chip package includes mounting a first chip die a first surface of an interposer. The interposer including a glass interposer core, first redistribution layers disposed on a first surface of the glass interposer core, and second redistribution layers disposed on a second surface of the glass interposer core. The method further includes mounting the interposer to a first surface of a substrate. The substrate including a glass substrate core, third redistribution layers disposed on a first surface of the glass substrate core, and fourth redistribution layers disposed on a second surface of the glass substrate core.

### BRIEF DESCRIPTION OF THE DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1A is a schematic sectional view of a chip package having an interposer and substrate with glass cores, and including a bridge die.

FIG. 1B is a schematic sectional view of a chip package having an interposer and substrate with glass cores.

FIG. 2 is a simplified schematic sectional view of a chip package having an interposer and substrate with glass cores.

FIG. 3 is a block diagram a computer system having a chip package having an interposer and substrate with glass cores.

FIG. 4 illustrates a flowchart of a method for fabricating a chip package having an interposer and substrate with glass cores.

To facilitate understanding, identical reference numerals have been used, where possible, to designate identical elements that are common to the figures. It is contemplated that elements of one example may be beneficially incorporated in other examples.

### DETAILED DESCRIPTION

Described herein is an improved chip package and methods for fabricating the same. The improved chip package utilizes substrates having glass cores to take advantage of the geometry of a glass panel for chip packaging and to support larger form factor packages. Typically, as the size of a package form factor increases, the package is more susceptible to warping. Warping increasing challenges that occur during the assembly process (e.g., a surface mount technology (SMT) process) increasing the possibility of failures occurring during the assembly process.

The improved chip package described herein includes a plurality of dies mounted to an interposer. In turn, the interposer is mounted to a substrate. The interposer and the substrate include glass cores. The properties of the glass cores can be adjusted to alter the coefficient of thermal expansion (CTE) of the interposer and the substrate, mitigating the effects of warpage (e.g., stresses) that may occur during the assembly process, decreasing failures that may occur during the assembly process. Accordingly, the improved chip package as described herein allows for larger form factor packages to be used and/or decreasing the corresponding semiconductor manufacturing costs.

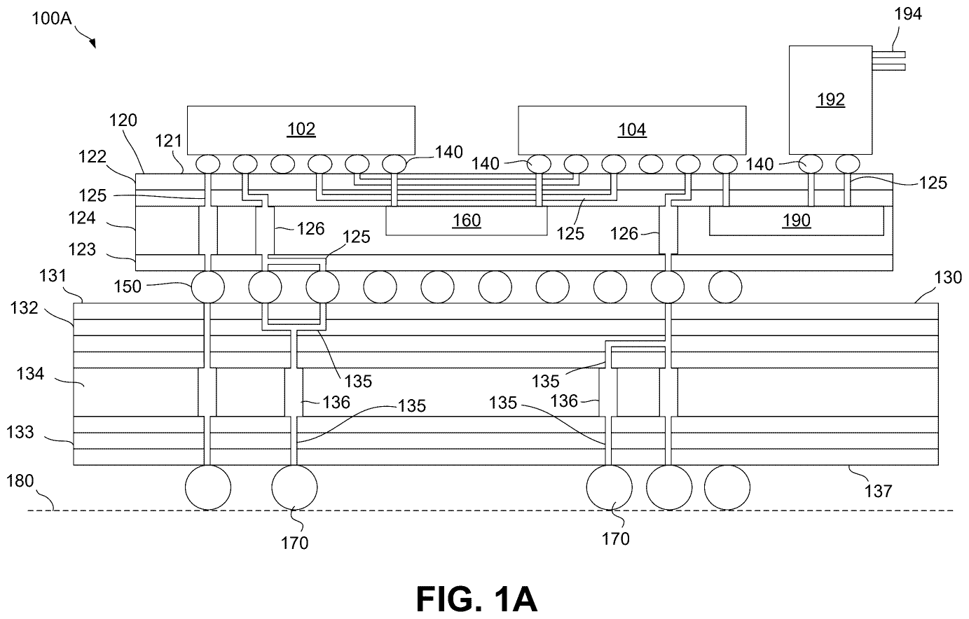

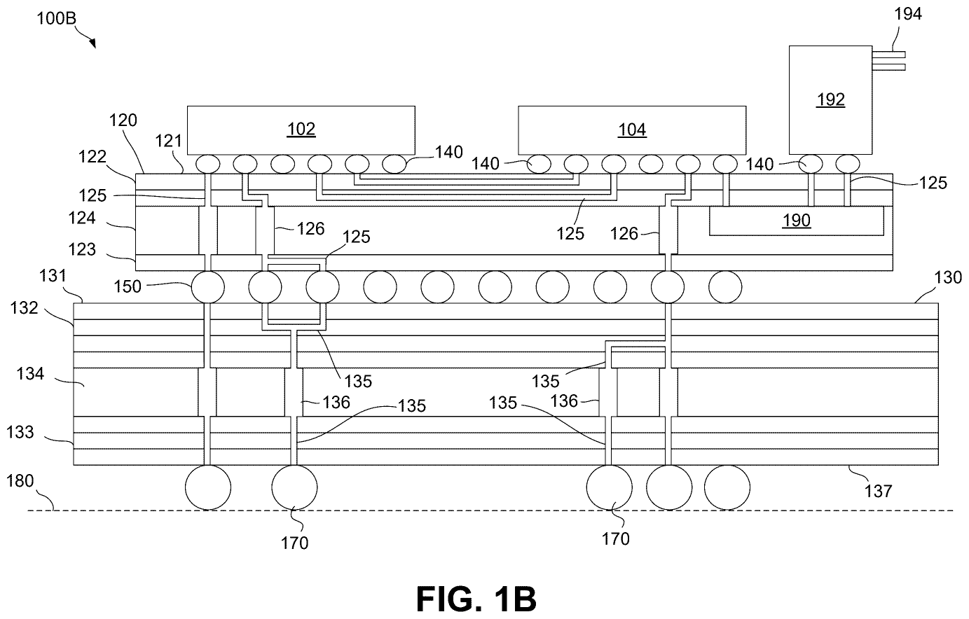

FIG. 1A is a schematic sectional view of a chip package 100A having a first chip die 102 and a second chip die 104, an interposer 120, and a substrate 130. The first and second chip dies 102 and 104 are laterally disposed on a top surface 121 of the interposer 120. For example, the first and second chip dies 102 and 104 are mounted to the surface 121 via the interconnects 140. The first and second chip dies 102 and 104 include exposed contact pads that are coupled (connected) to the interconnects 140 forming a physical and electrical connection between the contact pads and the interconnects 140.

The first and second chip dies 102 and 104 are integrated circuit (IC) chip dies. In one or more examples, one or more of the first and second chip dies 102 and 104 is a type of processing device (e.g., a central processing unit (CPU), graphics processing unit (GPU), or another type of processing device). In other examples, one or more of the first and second chip dies 102 and 104 is a memory device (e.g., a high bandwidth memory (HBM) or another type of memory) or another type of IC device.

The interposer 120 includes redistribution layers 122 and 123, and glass interposer core 124. The redistribution layers 122 and 123 are formed on either side of the glass interposer core 124. For example, a first one or more redistribution layers 122 are formed on a top surface of the glass interposer core 124, and a second one or more redistribution layers 123 are formed on a bottom surface of the glass interposer core 124. The redistribution layers 122 and 123 include metal and/or dielectric layers. The redistribution layers 122 and 123 are used to route connections between the chip dies 102 and 104 and/or from the chip dies 102 and 104 to other circuit elements. The redistribution layers 122 and 123 extend the pitch of the interconnects 140.

In one or more examples, internal routings 125 are formed within the redistribution layers 122 and 123 and the glass interposer core 124. The internal routings 125 provide communication between the chip dies 102 and 104 and the substrate 130. In one or more examples, one or more of the internal routings 125 provide communication between one or more of the chip dies 102 and 104 and the bridge die 160.

The glass interposer core 124 is formed from glass, and may be referred to as a glass core. In one example, the glass core may also be referred to as a glass wafer. The glass interposer core 124 may be formed from one or more of borosilicate, quartz material and fused silica, among others. The glass interposer core 124 provides mechanical base support for the semiconductor chip package and an electrical interface for the corresponding signal interconnects. The glass interposer core 124 includes vias 126. The vias 126 may be referred to as through glass vias. The vias 126 are formed as part of the internal routings 125. The vias 126 are formed through the entire thickness of the glass interposer core 124. In one or more examples, holes are manufactured into the glass interposer core 124 via masked isotropic wet etching glass and/or laser drilling. In one or more examples, glass if flown around fabricated metal rods positioned in a particular pattern. In other examples, other methods may be used to form the vias 126.

In one example, the vias 126 are formed within the glass interposer core 124 before the redistribution layers 122 and 123 are disposed on the glass interposer core 124. While not illustrated, conductive bump pads are formed at the vias 126 and on the surfaces of the glass interposer core 124. One or more organic layers (dielectric layers) and metal layers (conductive layers) may be disposed on one or more surfaces of the glass interposer core 124, and over the conductive bump pads. The organic layers and metal layers are patterned based on the internal routings 125.

The glass interposer core 124 has properties that make using a glass core a better candidate for use in an interposer than other types of interposers. For example, forming the glass interposer core 124 out of glass allows for the glass interposer core 124 to have an adjustable CTE that allows the glass interposer core 124 to match the CTE of silicon and other bonding materials. The glass interposer core 124 has a relatively low dielectric constant, a relatively high rigidity and strength, a relatively high resistivity, and thus, low electrical loss. In or more examples, the glass interposer core 124 has a smooth surface that does not require expensive polishing processes. Further, the glass interposer core 124 may be processed by relatively high temperature steps, higher than that of other types of substrate cores.

The substrate 130 includes redistribution layers 132 and 133, and glass substrate core 134. The redistribution layers 132 and 133 are formed on either side of the glass substrate core 134. For example, a first one or more redistribution layers 132 are formed on a top surface of the glass substrate core 134, and a second one or more redistribution layers 133 are formed on a bottom surface of the glass substrate core 134. The redistribution layers 132 and 133 include metal and/or dielectric layers. The redistribution layers 132 and 133 are used to route connections from the interconnects 150. The redistribution layers 132 and 133 extend the pitch of the interconnects 150. The substrate 130 is connected (e.g., physically and electrically) to the interposer 120 via the interconnects 150.

In one or more examples, internal routings 135 are formed within the redistribution layers 132 and 133 and the glass substrate core 134. The internal routings 135 provide communication between the interconnects 150 and circuit elements eternal to the substrate 130.

The glass substrate core 134 is formed from glass, and may be referred to as a glass core. In one example, the glass core may also be referred to as a glass wafer. The glass substrate core 134 may be formed from one or more of borosilicate, quartz material and fused silica, among others. The glass substrate core 134 provides mechanical base support for the semiconductor chip package and an electrical interface for the corresponding signal interconnects. The glass substrate core 134 includes vias 136. The vias 136 may be referred to as through glass vias. The vias 136 are formed as part of the internal routings 135. The vias 136 are formed through the entire thickness of the glass substrate core 134. In one or more examples, holes are manufactured into the glass substrate core 134 via masked isotropic wet etching glass and/or laser drilling. In one or more examples, glass if flown around fabricated metal rods positioned in a particular pattern. In other examples, other methods may be used to form the vias 136.

The glass substrate core 134 has properties that make using a glass core a better candidate for use in a substrate than other types of materials (e.g., organic materials). For example, forming the glass substrate core 134 out of glass allows for the glass substrate core 134 to have an adjustable CTE that allows the glass substrate core 134 to match the CTE of silicon and other bonding materials. The glass substrate core 134 has a relatively low dielectric constant, a relatively high rigidity and strength, a relatively high resistivity, and thus, low electrical loss. In or more examples, the glass substrate core 134 has a smooth surface that does not require expensive polishing processes. Further, the glass substrate core 134 may be processed by relatively high temperature steps, higher than that of other types of substrate cores.

In one example, the vias 136 are formed within the glass substrate core 134 before the redistribution layers 132 and 133 are disposed on the glass substrate core 134. While not illustrated, conductive bump pads are formed at the vias 136 and on the surfaces of the glass substrate core 134. One or more organic layers (dielectric layers) and metal layers (conductive layers) may be disposed on one or more surfaces of the glass substrate core 134, and over the conductive bump pads. The organic layers and metal layers are patterned based on the internal routings 135.

The substrate 130 may be referred to as a package substrate. The substrate 130 is connected to the interposer 120 via the interconnects 150. The interconnects 150 are mounted to the surface 131 of the substrate and may be, for example, controlled collapse chip connection (C4 balls). The interconnects 150 couple a portion of the circuitry of the interposer 120 to circuitry (e.g., internal routings 135 and vias 136) formed through the substrate 130. The interconnects 150 provide mechanical and electrical connections between the package substrate 130 and the first interposer 120.

Some of the internal routings 135 formed in the substrate 130 terminate at contact pads (not shown) exposed on a bottom surface 137 of the substrate 108 that faces away from the interposer 120. Interconnects (solder balls) 170 (e.g., ball grid array (BGA)) are disposed on the contact pads exposed on the bottom surface 137. The interconnects 170 are utilized to couple the chip package 100A to a printed circuit board 180 (shown in phantom) to form an electronic device.

The bridge die (or interconnect bridge) 160 provides communication between the first chip die 102 and the second chip die 104. In one example, the bridge die 160 is an embedded multi-die interconnect bridge (EMIB) die having high density routing. In another example, the bridge die 160 is a silicon-based integrated circuit die having internal high density solid state routing to provide communication between first chip die 102 and the second chip die 104. In some examples, the bridge die 160 configured as a silicon-based integrated circuit die has only solid state routing and no active circuit elements, such as transistors and the like. In one or more examples, the bridge die 160 is disposed (mounted) within a recess or cavity formed within the interposer 120. In one or more examples, the bridge die 160 may be disposed within the substrate 130 instead of the interposer 120.

In one or more examples, the chip package 100A includes a photonic connector 192 attached to the interposer 120. The photonic connector 192 includes a fiber optic cable 194 for connection to an optical device. A bottom surface of photonic connector 192 faces and overlaps the top surface 121 of the interposer 120. The Interconnects 140 couple circuitry of the photonic connector 192 to the internal routings 125 formed in the interposer 120. The interconnects 140 provide mechanical and electrical connections between the photonic connector 192 and the interposer 120. In one embodiment, an electric integrated circuit (EIC) 190 disposed in the interposer 120 provides communication between the second chip die 104 and the photonic connector 192. The EIC 190 may function as an electrical to optical converter. In some embodiments, a co-package cable (not shown) is mounted on the interposer 120.

In one or more examples, the first and second chip dies 102 and 104, the interposer 120, and the substrate 130 may be individually manufactured and assembled together to form the chip package 100A.

FIG. 1B is a schematic sectional view of a chip package 100B having the first chip die 102 and the second chip die 104, the interposer 120, and the substrate 130. The chip package 100B is configured similar to the chip package 100A of FIG. 1A. However, as compared to the example of the chip package 100A, the chip package 100B omits the bridge die 160. In the example of FIG. 1B, the first chip die 102 and the second chip die 104 are connected with each other via the internal routings 125. The internal routings 125 provide electrical connections between the first chip die 102 and the second chip die 104. The first chip die 102 and the second chip die 104 communicate with each via the internal routings 125. In one or more examples, the first chip die 102 and the second chip die 104 communicate with each other via the internal routings 125 and without an intervening bridge die.

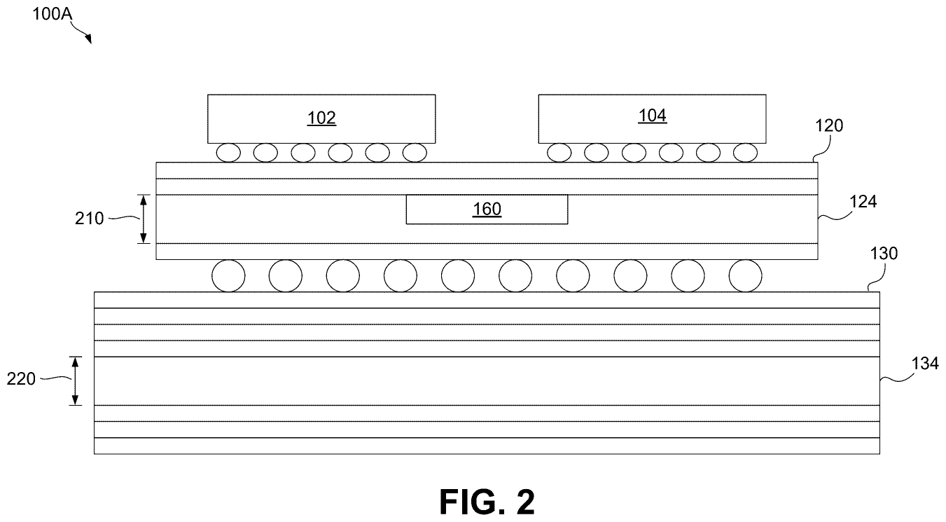

FIG. 2 illustrates a simplified view of the chip package 100A. As is illustrated in FIG. 2, the glass interposer core 124 has a thickness 210. The glass substrate core 134 has a thickness 220. In one example, the thickness 220 is greater than the thickness 210. In other examples, the thickness 220 is less than or equal to the thickness 220. The CTE of the glass interposer core 124 corresponds to the thickness 210. The CTE of the glass substrate core 134 corresponds to the thickness 220. In one or more examples, varying the thickness 210 varies the CTE of the glass interposer core 124. Additionally, or alternatively, varying the thickness 220 varies the CTE of the glass substrate core 134. In one or more examples, the CTE of the glass substrate core 134 is greater than the CTE of the glass interposer core 124. In one or more examples, the CTE of the glass substrate core 134 is equal to or less than the CTE of the glass interposer core 124. In one example, the CTE and thickness 220 of the glass substrate core 134 is greater than the CTE and thickness 210 of the glass interposer core 124.

In one example, the thickness 210 has a range of about 50 μm to about 800 μm. Further, the thickness 220 has a range from about 800 μm to about 2000 μm. In other examples, the thickness 210 and the thickness 220 may have other ranges of values, where the thickness 220 is greater than the thickness 210. In an example where the thickness 220 is greater than the thickness 210, the thickness 220 is a coarse adjustment to mitigate warping and/or other stresses that may occur during the assembly process, and the thickness 210 is a fine adjust that is used to fine-tune the mitigation of warping and/or other stresses that may occur during the assembly process.

In one example, one or more material properties of the glass interposer core 124 differs from one or more material properties of the glass substrate core 134. For example, the glass interposer core 124 is formed from a material that differs from a material used to form the glass substrate core 134. In one example, varying the material properties of the glass interposer core 124 and the glass substrate core 134 varies the corresponding CTEs.

In one or more examples, the CTEs of the glass interposer core 124 and the glass substrate core 134 are adjusted to mitigate any warping and/or other stresses that may occur during the assembly process. For example, smaller thickness 210 may be used with larger thicknesses 220 to mitigate the effects of warpage that may occur during the assembly process. In one example, the thickness of the glass interposer core 124 is 0.8 mm providing a CTE of 10 ppm, and the thickness of the glass substrate core 134 is 1 mm providing a CTE of 3.5 ppm. In another example, the thickness of the glass interposer core 124 is 0.8 mm providing a CTE of 10 ppm, and the thickness of the glass substrate core 134 is 2 mm providing a CTE of 7 ppm. Depending on the parameters of the corresponding chip package and the amount of warpage (and other stresses) that can be tolerated during the assembly process, the thickness of the glass interposer core 124 and the glass substrate core 134 are selected relative to each other. In one or more examples, the use of the glass interposer core 124 and the glass substrate core 134 allow for the support of a chip module size of about 90 mm×about 60 mm, or larger, and/or package form factors that are about 150 mm×about 115 mm, or larger. In one or more examples, the thickness 210 and the thickness 220 are determined during an IC design process based on the parameters of the corresponding chip package.

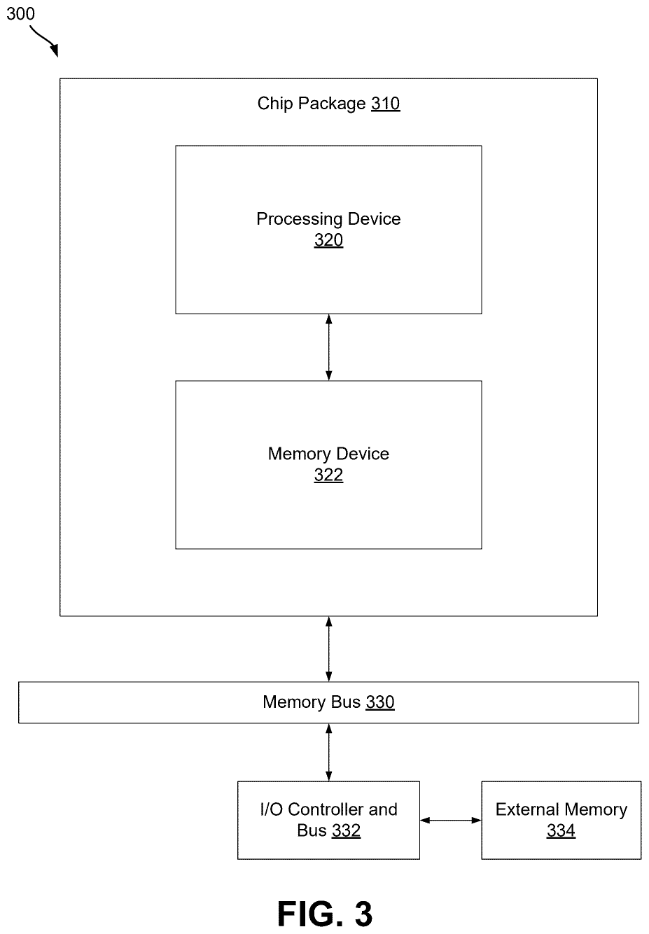

FIG. 3 illustrates a block diagram of a computing system 300 that utilizes a chip package 310 configured similar to the chip package 100A of FIG. 1A or chip package 100B FIG. 1B. The chip package 310 includes a processing device 320 and a memory device 322. The processing device 320 and the memory device 322 are configured similar to the chip dies 110 and 112 of FIG. 1A or FIG. 1B. The processing device 320 may be referred to as an IC device. The chip package 310 uses one of a ball grid array (BGA) surface mount package, a chip scale package (CSP), and a System in Package (SiP) that communicates with other components on a motherboard (e.g., the printed circuit board 180). In one or examples, the chip package 310 includes one of the processing device 320 and the memory device 322. Interfaces, such as a memory controller, a bus or a communication fabric, one or more phased locked loops (PLLs) and other clock generation circuitry, a power management unit, and so forth, are not shown for ease of illustration. Additionally, in the illustrated implementation, the chip package 310 is connected to the disk memory external memory through the memory bus 330 and the input/output (I/O) controller and bus 332.

It is understood that in other implementations, the computing system 300 includes one or more of other processors of a same type or a different type than processing device 320, one or more peripheral devices, a network interface, one or more other memory devices, and so forth. In some implementations, the functionality of the computing system 300 is incorporated on a system on chip (SoC). In other implementations, the functionality of the computing system 300 is incorporated on a peripheral card inserted in a motherboard. The computing system 300 is used in any of a variety of computing devices such as a desktop computer, a tablet computer, a laptop, a smartphone, a smartwatch, a gaming console, a personal assistant device, and so forth.

The processing device 320 includes hardware such as circuitry. In various implementations, the processing device 320 includes one or more processing units. In some implementations, each of the processing units includes one or more processor cores capable of general-purpose data processing, and an associated cache memory subsystem. In such an implementation, the processing device 320 is a CPU. In another implementation, the processing cores are compute units, each with a highly parallel data microarchitecture with multiple parallel execution lanes and an associated data storage buffer. In such an implementation, the processing device 320 is a GPU, a digital signal processor (DSP), or other.

In some implementations, the memory device 322 includes one of a variety of types of dynamic random access memories (DRAMs). In some implementations, the memory device 322 utilizes three-dimensional (3-D) packaging and includes memory dies placed horizontally next to the processing device 320 on the stacked glass package substrates with asymmetric metal layers. In another implementation, the memory device 322 utilizes 3-D packaging and includes additional memory dies vertically stacked on top of the memory dies placed horizontally next to the processing device 320 on the stacked glass package substrates. The memory device 322 stores at least a portion of an operating system and one or more applications represented by code.

In various implementations, the external memory 334 includes one or more hard disk drives (HDDs) and Solid-State Disks (SSDs) comprising banks of Flash memory. The I/O controller and bus 332 supports communication protocols with the external memory 334.

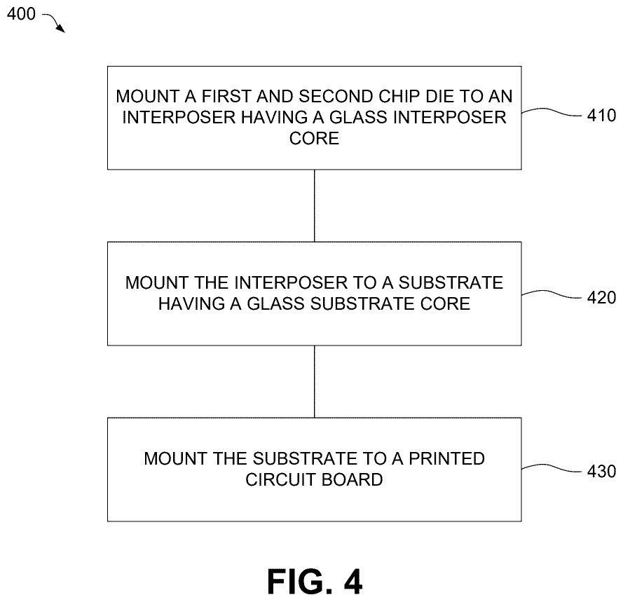

FIG. 4 is a flow diagram of a method 400 for fabricating a chip package having an interposer with a glass interposer core and a substrate with a glass substrate core. The method 400 may be utilized to fabricate the chip package 100A or the chip package 100B described above, or other similar chip packages.

The method 400 begins at operation 410, the first and second chip dies 102 and 104 are mounted to the interposer 120. The first and second chip dies 102 and 104 are mounted (e.g., disposed) on the surface 121 of the interposer 120 via the interconnects 140. The interposer 120 includes a glass interposer core 124 having a thickness 210. A filler material may be disposed on the interposer 120 to fill the inter-die gap laterally defined between the chip dies 102 and 104. In some embodiment, three or more dies may be mounted to the interposer 208.

In one example, the bridge die 160 is mounted within a cavity of the interposer 120 before the chip dies 102 and 104 are mounted to the interposer 120. The first and second chip dies 102 and 104 are electrically connected to the circuitry of the bridge die 160 to provide communication between the first and second chip dies 102 and 104.

At operation 420, the interposer is mounted to a substrate having a glass substrate core. For example, the interposer 120 is mounted to the substrate 130 via the interconnects 150. The interconnects 150 electrically and mechanically couple the interconnect 150 with the substrate 130. The substrate 130 includes the glass substrate core 134. In one example, the interposer 120 is mounted to the substrate 130 after the chip dies 102 and 104 are mounted to the interposer 120.

At operation 430, the substrate is mounted to a printed circuit board. For example, the substrate 130 is mounted to the printed circuit board 180 via the interconnects 170.

In one or more examples, optionally, a photonic connector 192 is mounted to the top surface of the interposer 120. An electric integrated circuit 190 is disposed in the glass interposer core 124 and connected to the photonic connector 192 via the interconnects 140. The electric integrated circuit 190 couples the photonic connector 192 to the second chip die 104. The photonic connector 192 may include a fiber optic cable 194 for connection to an optical device.

In one or more examples, mounting the chip dies 102 and 104 to the interposer 120 involves heating the interconnects 140, the chip dies 102 and 104, and the interposer 120, to reflow the interconnects 140 and to electrically and physically connect the chip dies 102 and 104 with the interposer 120. In one example, mounting the interposer 120 to the substrate 130 involves heating the interconnects 150, the interposer 120, and the substrate 130, to reflow the interconnects 150 and to electrically and physically connect the interposer 120 with the substrate 130. In one or more examples, mounting the substrate 130 to the printed circuit board 180 involves heating the interconnects 170 and the substrate 130 120, and the substrate 130, to reflow the interconnects 170 and to electrically and physically connect the substrate 130 with the printed circuit board 180. The process for mounting the various components of the chip package 100A or the chip package 100B with each other may be referred to a surface mount technology (SMT) process.

In one or more examples, during the mounting processes described with regard to operations 410, 420, and 430, the CTE of the glass interposer core 124 and the glass substrate core 134 mitigate warpage, mitigating assembly errors that may occur and faults within the final assembled device. The mitigation effects are especially useful in large form factor packages. Accordingly, the semiconductor manufacturing cost is reduced and larger form factor packages may be used.

While the foregoing is directed to specific examples, other and further examples may be devised without departing from the basic scope thereof, and the scope thereof is determined by the claims that follow.

What is claimed is:

1. A chip package comprising:
a substrate comprising a glass substrate core, first redistribution layers disposed on a first surface of the glass substrate core, and second redistribution layers disposed on a second surface of the glass substrate core;
an interposer comprising a glass interposer core, third redistribution layers disposed on a first surface of the glass interposer core, and fourth redistribution layers disposed on a second surface of the glass interposer core; and
a first chip die mounted to a first surface of the interposer.

2. The chip package of claim 1, wherein the glass substrate core comprises a first thickness, and the glass interposer core comprises a second thickness, and wherein the first thickness differs from the second thickness.

3. The chip package of claim 2, wherein the first thickness is larger than the second thickness.

4. The chip package of claim 3, wherein the glass substrate core comprises a first coefficient of first thermal expansion and the glass interposer core comprises a second coefficient of thermal expansion.

5. The chip package of claim 4, wherein the first coefficient of thermal expansion is greater than the second coefficient of thermal expansion.

6. The chip package of claim 1, wherein a bridge die is disposed within the glass interposer core, and the bridge die comprises circuitry that connects the first chip die with a second chip die.

7. The chip package of claim 1, further comprising a photonic connector mounted to the first surface of the interposer and configured to communicate with the first chip die.

8. A computer system comprising:
an integrated circuit device; and
a chip package connected to the integrated circuit device, the chip package comprising:
a substrate comprising a glass substrate core, first redistribution layers disposed on a first surface of the glass substrate core, and second redistribution layers disposed on a second surface of the glass substrate core;
an interposer comprising a glass interposer core, third redistribution layers disposed on a first surface of the glass interposer core, and fourth redistribution layers disposed on a second surface of the glass interposer core; and
a first chip die mounted to a first surface of the interposer.

9. The computer system of claim 8, wherein the glass substrate core comprises a first thickness, and the glass interposer core comprises a second thickness, and wherein the first thickness differs from the second thickness.

10. The computer system of claim 9, wherein the first thickness is larger than the second thickness.

11. The computer system of claim 10, wherein the glass substrate core comprises a first coefficient of first thermal expansion and the glass interposer core comprises a second coefficient of thermal expansion.

12. The computer system of claim 11, wherein the first coefficient of thermal expansion is greater than the second coefficient of thermal expansion.

13. The computer system of claim 8, wherein a bridge die is disposed within the glass interposer core, and the bridge die comprises circuitry that connects the first chip die with a second chip die.

14. The computer system of claim 8, wherein the chip package further comprises a photonic connector mounted to the first surface of the interposer and configured to communicate with the first chip die.

15. A method for fabricating a chip package, the method comprising:
mounting a first chip die a first surface of an interposer, the interposer comprising a glass interposer core, first redistribution layers disposed on a first surface of the glass interposer core and second redistribution layers disposed on a second surface of the glass interposer core; and
mounting the interposer to a first surface of a substrate, the substrate comprising a glass substrate core, third redistribution layers disposed on a first surface of the glass substrate core and fourth redistribution layers disposed on a second surface of the glass substrate core.

16. The method of claim 15, wherein the glass substrate core comprises a first thickness, and the glass interposer core comprises a second thickness, and wherein the first thickness differs from the second thickness.

17. The method of claim 16, wherein the first thickness is larger than the second thickness.

18. The method of claim 17, wherein the glass substrate core comprises a first coefficient of first thermal expansion and the glass interposer core comprises a second coefficient of thermal expansion.

19. The method of claim 18, wherein the first coefficient of thermal expansion is greater than the second coefficient of thermal expansion.

20. The method of claim 15 further comprising:
disposing a bridge die within the glass interposer core, and the bridge die comprises circuitry that connects the first chip die with a second chip die; and
mounting the substrate to a printed circuit board.
